(19) United States
(12) Patent Application Publication
(10) Pub. No.: US 2026/0122985 A1
(43) Pub. Date: Apr. 30, 2026

(54) SUPERJUNCTION DEVICE WITH IMPROVED EDGE TERMINATION

(71) Applicant: Infineon Technologies Austria AG, Villach (AT)

(72) Inventors: Maximilian Treiber, München (DE); Christian Fachmann, Villach (AT); Franz Hirler, Isen (DE); Winfried Kaindl, Unterhaching (DE)

(21) Appl. No.: 18/898,958

(22) Filed: Sep. 27, 2024

Related U.S. Application Data
(60) Provisional application No. 63/541,500, filed on Sep. 29, 2023.

(51) Int. Cl. H10D 62/10

(52) U.S. Cl. CPC H10D 62/111

(57) ABSTRACT

A semiconductor device includes a semiconductor body including a main surface, a rear surface, and an outer edge side; a superjunction structure including a plurality of superjunction columns that alternate in conductivity type along a lateral direction of the semiconductor body; an active region including a plurality of transistor cells; and a peripheral region laterally separating the active region from the outer edge side, the peripheral region being devoid of the transistor cells; wherein the superjunction structure includes a first cell region and a second cell region, wherein the superjunction columns in the second cell region have a lower dopant concentration than the superjunction columns in the first cell region, wherein the first cell region is disposed within a central part of the active region, and wherein the second cell region at least partially overlaps with an outer part of the active region that adjoins the peripheral region.

### BACKGROUND

Power semiconductor devices conduct a high load current and withstand a high blocking voltage. Superjunction devices are power semiconductor devices that include a superjunction structure with oppositely doped columns formed in a drift zone which is electrically arranged in series to controllable device channels. When a blocking voltage is applied to a superjunction configured device, a lateral electric field rises and clears out the mobile charge carriers along the vertical p-n junctions between the oppositely doped columns. A space charge begins to expand perpendicularly to the direction of a load current flow in the on-state. The mobile charge carriers are completely forced out of the superjunction structure at a comparatively low blocking voltage. When the blocking voltage is further increased, the depleted superjunction structure acts as a quasi-intrinsic layer and the vertical electric field rises. The breakdown voltage is decoupled from the dopant concentrations in the superjunction structure such that the dopant concentration in the superjunction structure can be comparatively high. Therefore, superjunction devices typically combine very low on-state resistance with high blocking capability. The more closely matched the oppositely doped columns are in dopant concentration, the greater efficiency of the superjunction structure in terms of blocking capability and semiconductor volume is realized.

There is a need to improve superjunction devices.

### SUMMARY

An embodiment of a semiconductor device comprises a semiconductor body comprising a main surface, a rear surface, and an outer edge side extending between the main surface and the rear surface; a superjunction structure comprising a plurality of superjunction columns that alternate in conductivity type along a lateral direction of the semiconductor body; an active region comprising a plurality of transistor cells, each of the transistor cells being configured to control a vertical current flowing through one of the superjunction columns; and a peripheral region laterally separating the active region from the outer edge side, the peripheral region being devoid of the transistor cells; wherein the superjunction structure comprises a first cell region and a second cell region, wherein the superjunction columns in the second cell region have a lower dopant concentration than the superjunction columns in the first cell region, wherein the first cell region is disposed within a central part of the active region, and wherein the second cell region at least partially overlaps with an outer part of the active region that adjoins the peripheral region.

An embodiment of a semiconductor device comprises a semiconductor body comprising a main surface, a rear surface, and an outer edge side extending between the main surface and the rear surface; a superjunction structure comprising a plurality of superjunction columns that alternate in conductivity type along a lateral direction of the semiconductor body; an active region comprising a plurality of transistor cells, each of the transistor cells being configured to control a vertical current flowing through one of the superjunction columns; a peripheral region laterally separating the active region from the outer edge side, the peripheral region being devoid of the transistor cells; and a groove formed in the main surface of the semiconductor body in the peripheral region, the groove being filled with a dielectric material, wherein a width an interior portion of the peripheral region is less than or equal to two times a cell pitch of the superjunction structure, the cell pitch being a separation distance between immediately adjacent superjunction columns of a same doping type in the superjunction structure, the width of the interior portion of the peripheral region being a lateral distance from a center of a gate trench from an outermost transistor cell from the active region a lower corner of the groove.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a superjunction configured semiconductor device from a cross-sectional perspective, according to an embodiment.

FIG. 2, which includes FIGS. 2A and 2B, illustrates a superjunction configured semiconductor device from a plan view perspective, according to an embodiment.

FIG. 3 illustrates dopant concentration profiles of superjunction configured semiconductor devices, according to embodiments.

FIG. 4 illustrates a close-up view of an interior portion of the peripheral region of a superjunction configured semiconductor device from a cross-sectional perspective, according to an embodiment.

### DETAILED DESCRIPTION

Embodiments of a superjunction configured power semiconductor device are disclosed herein. The semiconductor device comprises a superjunction structure formed by superjunction columns that alternate in conductivity type along a lateral direction of a semiconductor body. The power semiconductor device includes an active region and a peripheral region laterally separating the active region from an outer edge side of the semiconductor body. The active region comprises a plurality of transistor cells that are configured to control a vertical load current flowing through the semiconductor body. The peripheral region is devoid of the transistor cells and is designed to relax the electric field that builds up in the semiconductor body, thereby ensuring that breakdown does not occur near the outer edge side of the semiconductor body. Advantageously, the embodiments disclosed herein reduce the size of the peripheral region relative to the active region without sacrificing voltage blocking capability of the device. Thus, a greater proportion of the chip area is devoted to the transistor cells. Consequently, a greater current capacity may be realized for a given die size while maintaining voltage blocking capability.

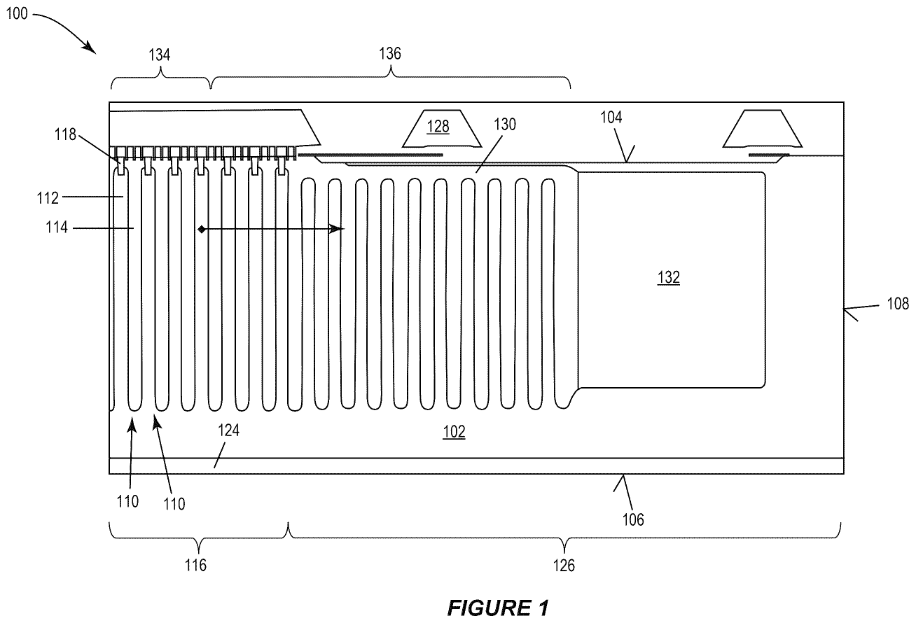

Referring to FIG. 1, a semiconductor device 100 is disclosed, according to an embodiment. The semiconductor device 100 is formed in a semiconductor body 102. The semiconductor body 102 may be formed from a single-crystalline semiconductor material such as silicon (Si), silicon carbide (SiC), germanium (Ge), a silicon germanium crystal (SiGe), gallium nitride (GaN), gallium arsenide (GaAs), etc.

The semiconductor body 102 comprises a main surface 104, a rear surface 106, and an outer edge side 108 extending between the main surface 104 and the rear surface 106. The main surface 104 may be an at least approximately planar surface and may comprise coplanar surface sections. The rear surface 106 may likewise be an at least approximately planar surface and may comprise coplanar surface sections parallel to the main surface 104. A minimum distance between the main and rear surfaces 104, 106 is selected to achieve a specified voltage blocking capability of the semiconductor device 100. The outer edge side 108 is a lateral surface that connects the main and rear surfaces 104, 106. The outer edge side 108 may be perpendicular to the main and rear surfaces 104, 106, for example.

The semiconductor body 102 comprises a superjunction structure. Examples of devices with superjunction structures and corresponding techniques for forming devices with superjunction structures are disclosed in U.S. Pat. No. 10,084,038B2, U.S. Pat. No. 10,468,479B2, and U.S. Pat. No. 11,211,483, the content of each document being incorporated by reference herein in its entirety. The superjunction structure comprises a plurality of superjunction columns 110 that alternate in conductivity type along a lateral direction of the semiconductor body 102. In particular, the superjunction structure comprises first conductivity type columns 112 and second conductivity type columns 114 with an opposite conductivity type as the first conductivity type columns 112 arranged alternatingly with one another along the lateral direction of the semiconductor body 102. At least in the active transistor area, the net dopant concentration of the superjunction columns 110 is selected to be high so that the drift region contribution to the on-resistance of the device can be maintained low. For example, a net dopant concentration the superjunction columns 110 may be in the range of 1E15 dopant atoms/cm³ to 1E18 dopant atoms/cm³ in the active transistor area. Moreover, the net dopant concentration of the first conductivity type columns 112 may be substantially equal to the net dopant concentration of the adjoining second conductivity type columns 114, e.g., within 20%, within 10%, within 5% so as to maintain compensation principle. The below discussion refers to superjunction unit cells. These superjunction unit cells correspond to pairs of the superjunction columns 110 that immediately adjoin and form a p-n junction with one another, i.e., a first conductivity type column 112 adjoining a second conductivity type column 114. The superjunction structure consists of multiple superjunction unit cells formed in a pattern. These superjunction unit cells may be formed according to a regular pitch. The superjunction structure may be formed in a variety of ways. For example, the superjunction structure may be formed by a multi-epi/multi-implant process, wherein multiple epitaxial layers are grown, dopants are implanted into surfaces of the epitaxial layers, and the process is repeated. Alternatively, the superjunction structure may be formed by forming a thick epitaxial sublayer, forming trenches in the thick epitaxial sublayer and, e.g., implanting dopants through sidewalls of the trenches or depositing doped layers in the trenches.

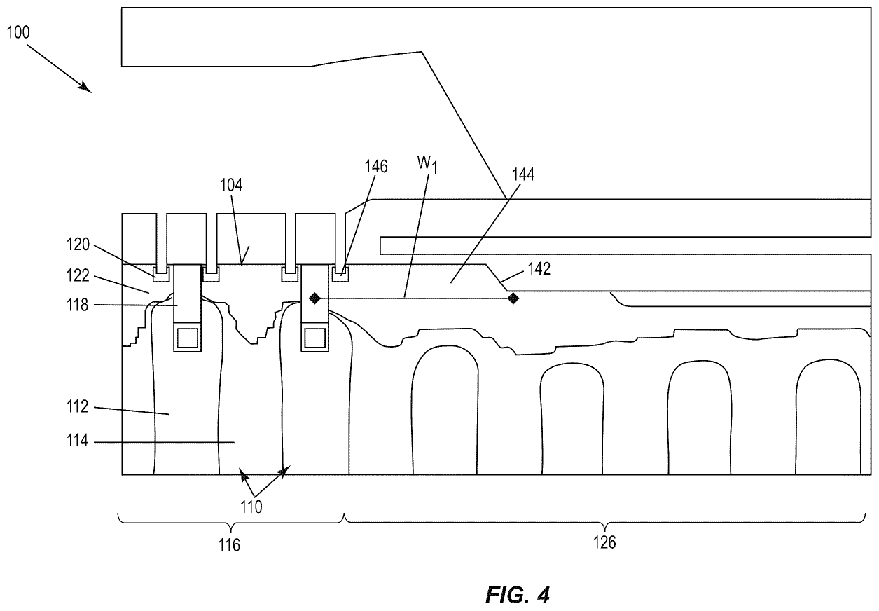

The semiconductor body 102 comprises an active region 116. The active region 116 comprises a plurality of transistor cells. The transistor cells are configured to control a vertical load current flowing between the main surface 104 and the rear surface 106. The transistor cells may be configured as MOSFET cells or IGBT cells, for example. Each transistor cell comprises a gate electrode 118. As shown, the gate electrode 118 may be provided within a trench. Alternatively, the gate electrode 118 may be a planar electrode disposed on a surface of the semiconductor body 102. Each transistor cell comprises a first conductivity type (e.g., n-type) source/emitter region 120 (seen in FIG. 4) arranged at the main surface 104 and a second conductivity type (e.g., p-type) body region 122 (seen in FIG. 4) interposed between the source/emitter regions 120 and the rear surface 106 of the semiconductor body 102. The body regions 122 may be created by a single doped layer formed in the main surface 104, with the source/emitter regions 120 corresponding to localized implants within the single doped layer. The semiconductor body 102 comprises a drain/collector region 124 at the rear surface 106 of the semiconductor body 102. The drain/collector region 124 may be provided by a highly doped first conductivity type layer in the case of a MOSFET or highly doped second conductivity type layer in the case of an IGBT. In a commonly known manner, each gate electrode 118 controls a current flowing from the source/emitter regions to the drain/collector of the device. The first conductivity type columns 112 form the drift region of the device such that the transistor current flows through these superjunction columns 110 in an on-state of the device and these superjunction columns 110 maintain a voltage potential in a blocking state of the device. The second conductivity type columns 114 facilitate higher doping of the first conductivity type columns 112 by compensating for the charges present in these superjunction columns 110 and thereby lower the on-resistance of the device, while maintaining off-state blocking voltage. At an outer boundary of the active region 116, the outermost second conductivity type column 114 that is connected with the source regions is actively conductive in both directions and thus accommodates a vertical forward and reverse current of the semiconductor device 100.

The semiconductor body 102 comprises a peripheral region 126. The peripheral region 126 laterally separates the active region 116 from the outer edge side 108. That is, the peripheral region 126 is interposed between the active transistor cells and the chip edge. According to an embodiment, from a plan-view perspective of the semiconductor body 102, the peripheral region 126 forms an enclosed ring that completely surrounds the active region 116. That is, the peripheral region 126 forms a complete buffer that separates the active transistor cells from the chip edge in every direction. The peripheral region 126 is devoid of transistor cells. That is, the peripheral region 126 refers to a portion of the semiconductor body 102 that does not include controllable structures for controlling a load current flowing between the main surface 104 and the rear surface 106 of the semiconductor body 102. The outermost transistor cell of the active region 116 forms a boundary with the peripheral region 126. As will be explained in further detail below, the superjunction structure maybe extended into the peripheral region 126. However, the superjunction unit cells of the peripheral region 126 are distinguished from the superjunction unit cells of the active region 116 in that there is no gate structure and/or source/emitter region formed above them, and thus and active transistor device current does not flow through these superjunction unit cells. Thus, the boundary between the active region 116 and the peripheral region 126 occurs at the interface between the outermost superjunction unit cell from the active region 116 which forms the drift structure of an active transistor device and the innermost superjunction unit cell from peripheral region 126 which does not form part of an active transistor device.

The peripheral region 126 comprises edge termination features that are configured to enhance the voltage blocking capability of the device by preventing large equipotential gradients from occurring near the outer edge side 108 of the semiconductor body 102. In particular, the superjunction structure may be extended into the peripheral region 126 and the doping concentration may be decreasingly graded towards the outer edge side 108 in a manner that will be described in further detail below. Additionally, the peripheral region 126 may comprise a field plate electrode 128 disposed at the main surface 104 of the semiconductor body 102, a so-called junction termination extension (JTE) region 130 bridging together multiple superjunction columns 110, and an intrinsically or very lightly doped outer region 132 disposed between the superjunction structure and the outer edge side 108 of the semiconductor body 102. The depicted peripheral region 126 represents just one exemplary edge termination configuration. The concepts disclosed herein, and in particular the superjunction structure doping and the width of the interior portion of the peripheral region 126, are applicable to a wide variety of different edge termination configurations, including any of the edge termination configurations discussed in the above referenced patent documents.

The superjunction structure is configured with a first cell region 134 and a second cell region 136. The first cell region 134 is disposed within a central part of the active region 116. That is, the first cell region 134 refers to a group of the superjunction unit cells that are completely contained within the active region 116. Thus, each of the superjunction unit cells from the first cell region 134 form one of the transistor cells. The second cell region 136 at least partially overlaps with an outer part of the active region 116 that adjoins the peripheral region 126. That is, the second cell region 136 includes at least one of the superjunction unit cells at the outer periphery of the active region 116 that forms one of the transistor cells. The second cell region 136 may additionally extend into the peripheral region 126. Thus, the second cell region 136 includes both superjunction unit cells from the outer part of the active region 116 and superjunction unit cells that do not form part of an active transistor device. In general, the number of superjunction unit cells from the second cell region 136 that overlap with the active region 116 may be no more than 20, no more than 15, no more than 10, no more than 5, no more than 3, etc. Stated in percentage terms, the overlap between the second cell region 136 and the active region 116 may account for no more than 10%, no more than 5%, or no more than 1% of the overall area of the active region 116.

The superjunction structure is configured such that the superjunction columns 110 in the second cell region 136 have a lower dopant concentration than the superjunction columns 110 in the first cell region 134. In this context, the dopant concentration of the superjunction columns 110 refers to a mean dopant concentration throughout the respective superjunction column 110. This dopant concentration can be expressed in terms of an integrated dopant concentration taken from top to bottom of the respective superjunction column 110. In a configuration wherein the superjunction columns 110 in the second cell region 136 have a lower dopant concentration than the superjunction columns 110 in the first cell region 134, the mean dopant concentration of each of the superjunction columns 110 in the first cell region 134 is at or above a first magnitude, and the mean dopant concentration each of the superjunction columns 110 in the second cell region 136 is no higher than a second magnitude that is below the first magnitude. According to an embodiment, the dopant concentration of the each of the superjunction unit cells in the first cell region 134 is substantially identical. This means that each of the first conductivity type columns 112 is nominally doped to have the same concentration, each of the second conductivity type columns 114 is nominally doped to have the same concentration, and any difference in dopant concentration between the first conductivity type columns 112 and the second conductivity type columns 114 is maintained below a predefined threshold to maintain charge compensation, e.g., within +/−10%, +/−5%, etc. In a more particular embodiment, the first conductivity type columns 112 and the second conductivity type columns 114 of each unit cell have the same dopant concentration. In the second cell region 136, the superjunction unit cells are configured such that at least one of the first conductivity type columns 112 and the second conductivity type columns 114 has a lower dopant concentration than the counterpart superjunction columns 110 from the first cell region 134. As a result, the superjunction unit cell from the second cell region 136 that overlaps with the active region 116 consists of at least one superjunction unit cell with at least one superjunction column that is more lightly doped than its counterpart doping type superjunction columns 110 from the first cell region 134.

According to an embodiment, the superjunction structure is configured such that the superjunction columns 110 in the second cell region 136 decrease in dopant concentration in a lateral direction moving away from the active region 116 and towards the outer edge side 108. This decrease may occur according to a variety of different schemes or patterns. According to an embodiment, in the second cell region 136, a dopant concentration of each of the superjunction columns 110 decreases relative to an immediately laterally adjacent superjunction column moving in the lateral direction towards the outer edge side 108. That is, the decrease in dopant concentration superjunction occurs on a column-by-column basis. For example, an outermost one of the superjunction columns 110 from the first cell region 134 may have a first dopant concentration, an innermost one of the superjunction columns 110 from the second cell region 136 that adjoins the outermost one of the superjunction columns 110 from the first cell region 134 may have a second dopant concentration that is lower than the first dopant concentration, a subsequent one of the superjunction columns 110 from the second cell region 136 that adjoins the innermost one of the superjunction columns 110 from the second cell region 136 may have a third dopant concentration that is lower than the second dopant concentration, and so forth. According to an embodiment, in the second cell region 136, a dopant concentration of each superjunction unit cell decreases relative to an immediately laterally adjacent superjunction unit cell moving in the lateral direction towards the outer edge side 108. That is, the decrease in dopant concentration superjunction occurs on a unit cell-by-unit cell basis. For example, an outermost one of the superjunction unit cells from the first cell region 134 may be configured such that each superjunction column is doped at a first dopant concentration, an innermost one of the superjunction unit cells from the second cell region 136 may be configured such that each superjunction column is doped at a second dopant concentration that is below the first dopant concentration, a subsequent one of the superjunction unit cells from the second cell region 136 may be configured such that each superjunction column 110 is doped at a third dopant concentration that is below the second dopant concentration, and so forth. According to another embodiment, in the portion of the second cell region 136 that overlaps with the active area 116, the dopant concentration of each superjunction unit cell decreases relative to the immediately laterally adjacent superjunction unit cell moving in the lateral direction towards the outer edge side 108. This decrease may occur across ten or fewer of the superjunction unit cells, five or fewer of the superjunction unit cells, three or fewer of the superjunction unit cells, and so forth. Thereafter, the dopant concentration of each superjunction unit cell within the peripheral region 126 may remain substantially constant, e.g., within about 10% of one another moving in the lateral direction towards the outer edge side 108. Separately or in combination, the dopant concentration of the superjunction columns 110 in the peripheral region 126 is configured to maintain a same shape of a lateral electric field. That is, the dopant concentration of the superjunction columns 110 as between laterally immediately adjacent ones of the superjunction columns 110 is identiacal or substantially identical such that the lateral electric field between the two remains constant. Meanwhile, the vertical dopant profile of the superjunction columns 110 may vary, e.g., by increasing towards a vertical center of the device. However, the vertically graded profile may remain consistent across laterally adjacent ones of the superjunction columns 110 to maintain a constant lateral electric field. More generally, any scheme or pattern that gradually decreases the dopant concentration of the superjunction columns 110 may be employed. The change in dopant concentration may follow a linear function or may follow more complex functions.

A superjunction structure with the above-described graded dopant profile may be realized by employing dopant techniques whereby the dopant dose used to form the superjunction columns 110 is changed along the lateral direction. In more detail, as explained above, the superjunction structure may be formed by a multi-epi/multi-implant process. In that case, the patterned masks formed on each of the epitaxial layers may be configured with differently sized openings moving in a lateral direction towards the outer edge side 108 of the semiconductor body 102. The superjunction columns 110 in the first cell region 134 may be formed from mask openings that are as large to the extent permitted by lithography, thereby facilitating the maximum implant dosage. The size of these openings may be gradually reduced as the implantation mask approaches the outer edge side 108 of the semiconductor body 102 and may approach or reach the minimum opening size of the mask, thereby decreasing the implant dosage as the superjunction columns 110 in these regions. In the case that the superjunction columns 110 are formed implanting dopants through sidewalls of the trenches or by depositing doped layers in the trenches, similar masking techniques can be employed to change the amounts of dopants implanted into the semiconductor material moving in a lateral direction towards the outer edge side 108 of the semiconductor body 102.

By configuring the superjunction structure to comprise superjunction columns 110 in the outer periphery of the active region 116 with a lower dopant concentration than the superjunction columns 110 in the remaining central part of the active region 116, an advantageous reduction in die area is possible while maintaining voltage rating. In more detail, the configuration of the superjunction structure whereby the dopant concentration of the superjunction columns 110 decrease in lateral direction moving towards the outer edge side 108 reduces the electric field gradient and increases the effective breakdown voltage in the outer edge region of the chip. The decreasing dopant concentration of the superjunction columns 110 must occur gradually over many superjunction columns 110 so that immediately adjacent superjunction columns 110 remain in a relatively compensated arrangement, i.e., the superjunction principle is maintained. By starting the reduction in dopant concentration within the active region 116, the number of superjunction unit cells needed in the edge region to achieve the necessary field shaping for a given breakdown strength is reduced. As a result, the size of the edge termination can be reduced, and consequently the ratio between the active region 116 and the peripheral region 126 can be increased, while maintaining a given voltage blocking rating. As a result, a greater proportion of the chip area is devoted to active transistor cells, leading to a favorable current rating per die size.

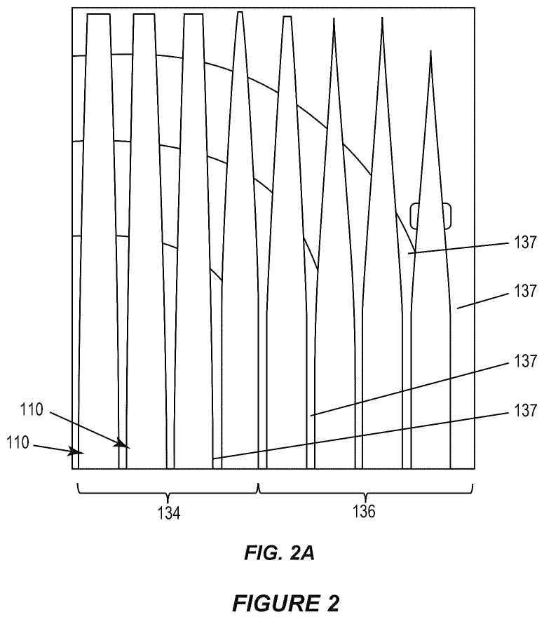

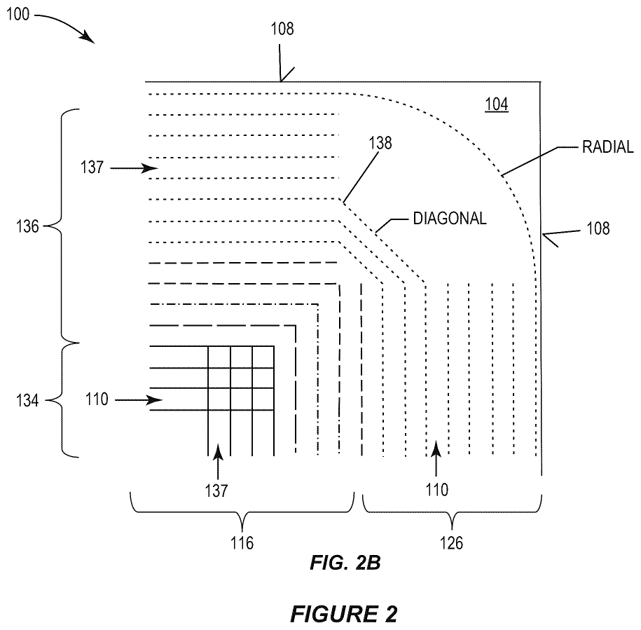

Referring to FIG. 2, a plan-view perspective of the superjunction configured semiconductor device 100 is shown, according to an embodiment. FIGS. 2A and 2B show the layout of the superjunction columns 110 at a corner of the semiconductor body 102. Similar arrangements may be provided at every other corner of the semiconductor body 102. As shown in FIG. 2A, the width of the superjunction columns 110 may change as the superjunction columns 110 approach the outer edge side 108. In the X direction of FIG. 2A, the width of the superjunction columns 110 may reduce as the superjunction columns approach the outer edge side 108. For example, the width of the superjunction columns 110 may reduce from about 1.3 μm-1.5 μm to about 0.7 μm-0.9 μm and/or by about 30%-50% moving in the X direction. In the Y direction of FIG. 2A, the width of the superjunction columns 110 gradually tapers as the superjunction columns 110 approach the outer edge side 108. FIG. 2A illustrates same dopant-level regions 137. These regions represent the relative dopant concentration of the superjunction columns 110. Thus, the same dopant-level region 137 within a center of the semiconductor body 102 correspond to the region in which the superjunction columns 110 are most highly doped, followed by an outer same dopant-level region 137 in which the doping concentration of the superjunction columns 110 is reduced. As shown, the same dopant-level region 137 may be configured as enclosed rings that surround the active region 116. FIG. 2B shows a potential geometry of the same dopant-level regions 137 at a corner of the semiconductor body 102. As shown in the figure, the same dopant-level regions 137 may be arranged with linear rows and columns perpendicular to the rows, with gradual transitions between the rows and columns at the corner of the semiconductor body 102. Alternatively, the same dopant-level regions 137 may have other types of gradual transitions, such as radial or curved transitions. This may be used to provide charge reduction near the corner of the semiconductor body.

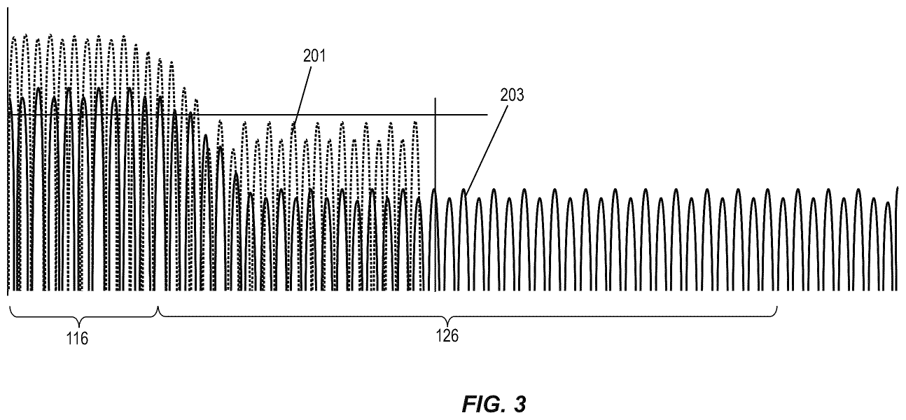

Referring to FIG. 3, a graph showing the dopant concentrations of two different superjunction configured semiconductor devices are shown. Curve 201 shows a dopant profile of a superjunction configured semiconductor device wherein the superjunction columns 110 in the outer periphery of the active region 116 decrease in dopant concentration. Curve 203 shows a dopant profile of a superjunction configured semiconductor device 100 wherein the decrease in dopant concentration only occurs in the superjunction columns 110 disposed outside of the active region 116. The local peaks in each curve correspond to the dopant concentrations observed in the first conductivity type columns 112 or second conductivity type columns 114, as the case may be. As can be seen, the device represented by curve 201 contains far fewer superjunction columns 110 in the peripheral region 126 than the device represented by curve 203, leading to a greater proportional share of the die being devoted to the active transistor area. Advantageously, due to the earlier lowering of the dopant concentrations within the active region 116, a similar edge termination effect is realized and the two devices may have a comparable voltage rating.

Referring to FIG. 4, a close-up view of a superjunction configured semiconductor device 100 is shown from a cross-sectional perspective, according to an embodiment. The semiconductor device 100 of FIG. 4 is a super junction device having a plurality of superjunction columns 110 that alternate in conductivity type along a lateral direction of the semiconductor body 102. The superjunction structure may be configured to have a second cell region 136 that overlaps with an outer part of the active region 116 and has superjunction columns 110 with a lower dopant concentration than the superjunction columns 110 in the first cell region 134, as described above with reference to FIG. 1.

The semiconductor device 100 comprises a groove 142 formed in the main surface 104 of the semiconductor body 102. This groove 142 is formed in the peripheral region 126 and may extend to the outer edge side 108 (as shown in FIG. 1) of the semiconductor body 102. The groove 142 is filled with a dielectric material. For example, the groove 142 may be filled by a thermally grown oxide or nitride, e.g., SiO₂, SiN, SiO_{X}N_{Y}, etc. The semiconductor device 100 comprises a body contact region 144 that extends from the main surface 104 into the semiconductor body 102 and is disposed between the active region 116 and the groove 142. The body contact region 144 is a second conductivity type region (e.g., p-type) that forms a contact with the second conductivity type columns 114 from the peripheral region 126. The semiconductor device 100 comprises a body contact 146 that is formed on the main surface 104 of the semiconductor body 102 and is in low ohmic contact with the body contact region 144. This body contact 146 may be connected with source/emitter potential, for example.

The semiconductor device 100 is configured such that a width W₁ of an interior portion of the peripheral region 126 is less than or equal to two times a cell pitch Cp of the superjunction structure. The interior portion refers to a portion of the peripheral region 126 accommodating non-transistor superjunction unit cells, i.e., superjunction unit columns that do not form part of active transistors that are closest to the active region 116. Instead, these superjunction unit cells form part of a structure that dissipates second conductivity type carriers through the body contact 146 during a switching operation. The interior portion of the peripheral region 126 extends from a center of the gate trench from an outermost one of the transistor cells from the active region 116 to a lower corner of the groove 142. The cell pitch Cp refers to a separation distance between immediately adjacent superjunction columns 110 of the same doping type in the superjunction structure. Thus, each of the first conductivity type columns 112 are separated from immediately adjacent first conductivity type columns 112 by an amount equal to one times the cell pitch Cp.

According to an embodiment, the width W₁ of the interior portion of the peripheral region 126 may be equal to between one and two times the cell pitch Cp of the superjunction structure. More particularly, the width W₁ of the interior portion of the peripheral region 126 is approximately 1.5 times the cell pitch Cp of the superjunction structure. From a plan-view perspective, the groove 142 may form a rounded transition at a corner of a semiconductor device 100 in a similar manner as the same dopant-level region 137 described above with reference to FIG. 2. According to an embodiment, when seen from a plan-view perspective of the semiconductor device, a radius of the groove 142, i.e., the radius of the rounded transition, is equal to between one and two times the cell pitch Cp of the superjunction structure. More particularly, the radius of the groove 142.

In a superjunction structure, with each switching operation, very high current densities are generated in the edge region during fast switching due to the high output charge from the edge area. In particular, the second conductivity type current (e.g., hole current) from the peripheral region 126 must flow to the outermost body contact 146 on the surface. This is problematic. On the one hand, the high current density always causes a high ohmic power dissipation, which lowers the switching efficiency of the transistor. On the other hand, at high current density, a high voltage drop arises, which is able to control a parasitic NPN bipolar transistor between source/emitter, body and drain/collector. This can create a latch-up condition that must be avoided, as it can damage the transistor in certain operating conditions.

In a superjunction configured semiconductor device 100 having the narrow separation distance between the active region 116 and the groove 142 as described above, the above-mentioned parasitic NPN transistor can be designed to be more robust, as the distance between source/emitter end and body contact 146 can be selected smaller. The body contact region 144 may have a higher dopant concentration so that the effective base-emitter voltage is lower at the same current. Due to modern lithography techniques, a charge reduction can be carried out within the active cell region as described above and may be more pronounced in the peripheral region 126, with the result being a device with significantly lower output charge in the peripheral region 126. Furthermore, the width of the outer body contact 146 can advantageously be made smaller. According to an embodiment, a width of the body contact 146 in contact with the body contact region 144 of the interior portion of the peripheral region 126 has the same width as each of the interior body contacts that are used in the active transistor cells. That is, the body contact 146 hole may be formed at the minimum size corresponding to the contact hole used in the active region 116. The source/collector implant may be omitted from the outermost gate trench sidewall to improve the robustness of the parasitic NPN transistor.

Although the present disclosure is not so limited, the following numbered examples demonstrate one or more aspects of the disclosure.

Example 1. A semiconductor device, comprising: a semiconductor body comprising a main surface, a rear surface, and an outer edge side extending between the main surface and the rear surface; a superjunction structure comprising a plurality of superjunction columns that alternate in conductivity type along a lateral direction of the semiconductor body; an active region comprising a plurality of transistor cells, each of the transistor cells being configured to control a vertical current flowing through one of the superjunction columns; and a peripheral region laterally separating the active region from the outer edge side, the peripheral region being devoid of the transistor cells, wherein the superjunction structure comprises a first cell region and a second cell region, wherein the first cell region is disposed within a central part of the active region, and wherein the second cell region at least partially overlaps with an outer part of the active region that adjoins the peripheral region, and wherein the superjunction columns in the second cell region have a lower dopant concentration than the superjunction columns in the first cell region.

Example 2. The semiconductor device of example 1, wherein the superjunction structure comprises a plurality of superjunction unit cells formed by adjacent pairs of the superjunction columns, and wherein the second cell region comprises at least one of the superjunction unit cells overlapping with the active region.

Example 3. The semiconductor device of example 2, wherein the second cell region comprises no more than three of the superjunction unit cells overlapping with the active region.

Example 4. The semiconductor device of example 2, wherein in the first cell region a dopant concentration of the each of the superjunction unit cells is substantially identical.

Example 5. The semiconductor device of example 1, wherein in the second cell region a dopant concentration of each of the superjunction columns decreases relative to an immediately laterally adjacent superjunction column moving in the lateral direction towards the outer edge side.

Example 6. The semiconductor device of example 1, wherein the second cell region is comprised of a plurality of the superjunction unit cells, and wherein in the second cell region a dopant concentration of each superjunction unit cell decreases relative to an immediately laterally adjacent superjunction unit cell moving in the lateral direction towards the outer edge side.

Example 7. The semiconductor device of example 1, wherein the second cell region overlaps with the peripheral region.

Example 8. The semiconductor device of example 7, wherein in the second cell region a dopant concentration of each of the superjunction columns decreases relative to an immediately laterally adjacent superjunction column moving in the lateral direction towards the outer edge side.

Example 9. The semiconductor device of example 1, wherein from a plan-view perspective of the semiconductor body, a dopant concentration of the of the superjunction columns is defined by same dopant-level regions, and wherein the same dopant-level regions form an enclosed ring that completely surrounds the active region.

Example 10. The semiconductor device of example 9, wherein from the plan-view perspective of the semiconductor body each of the same dopant-level regions within the active region form perpendicular corners with one another.

Example 11. The semiconductor device of example 1, wherein at an outer boundary of the active region, an outermost second conductivity type column is actively conductive in both directions.

Example 12. The semiconductor device of example 1, wherein in the peripheral region, the superjunction columns are arranged to maintain a same shape of an electric field as an electric field in the active region.

Example 13. The semiconductor device of example 1, wherein the peripheral region comprises an intrinsically or very lightly doped outer region disposed between the superjunction structure and the outer edge side of the semiconductor body.

Example 14. A semiconductor device, comprising: a semiconductor body comprising a main surface, a rear surface, and an outer edge side extending between the main surface and the rear surface; a superjunction structure comprising a plurality of superjunction columns that alternate in conductivity type along a lateral direction of the semiconductor body; an active region comprising a plurality of transistor cells, each of the transistor cells being configured to control a vertical current flowing through one of the superjunction columns; a peripheral region laterally separating the active region from the outer edge side, the peripheral region being devoid of the transistor cells; and a groove formed in the main surface of the semiconductor body in the peripheral region, the groove being filled with a dielectric material, wherein a width an interior portion of the peripheral region is less than or equal to two times a cell pitch of the superjunction structure, the cell pitch being a separation distance between immediately adjacent superjunction columns of a same doping type in the superjunction structure, the width of the interior portion of the peripheral region being a lateral distance from a center of a gate trench from an outermost transistor cell from the active region a lower corner of the groove.

Example 15. The semiconductor device of example 14, wherein the width of the interior portion of the peripheral region is between one and two times the cell pitch of the superjunction structure.

Example 16. The semiconductor device of example 14, wherein the interior portion of the peripheral region comprises a body contact region that extends from the main surface between the outermost one of the superjunction columns from the active region and the lower corner of the groove, wherein the body contact region is a highly doped region of a second conductivity type.

Example 17. The semiconductor device of example 16, wherein the semiconductor device comprises a plurality of interior body contacts within the active region and a first outer body contact disposed adjacent the outermost one of the superjunction columns, wherein the first outer body contact forms a low-ohmic connection with the body contact region, and wherein a width of the first outer body contact is that same as a width of each of the interior body contacts.

Example 18. The semiconductor device of example 17, wherein a transistor cell from the outermost one of the superjunction columns comprises only one source region disposed on an inner side of the transistor cell opposite from the peripheral region.

Example 19. The semiconductor device of example 17, wherein the superjunction structure comprises a first cell region and a second cell region, wherein the superjunction columns in the second cell region have a lower dopant concentration than the superjunction columns in the first cell region, wherein the first cell region is disposed within a central part of the active region, wherein the second cell region at least partially overlaps with an outer part of the active region that adjoins the peripheral region.

Example 20. The semiconductor device of example 19, wherein in the second cell region a dopant concentration of each of the superjunction columns decreases relative to an immediately laterally adjacent superjunction column moving in a lateral direction towards the outer edge side.

Example 21. The semiconductor device of example 20, wherein the second cell region overlaps with the interior portion of the peripheral region.

Example 22. The semiconductor device of example 14, wherein from a plan-view perspective the groove comprises a radius, and wherein the radius is less than or equal to two times the cell pitch of the superjunction structure.

The present specification refers to a “first” and a “second” conductivity type of dopants, semiconductor portions are doped with. The first conductivity type may be n type and the second conductivity type may be p type or vice versa. As is generally known, depending on the doping type or the polarity of the source and drain regions, insulated gate field effect transistors (IGFETs) such as metal oxide semiconductor field effect transistors (MOSFETs) may be n-channel or p-channel MOSFETs. For example, in an n-channel MOSFET, the source and the drain region are doped with n-type dopants. In a p-channel MOSFET, the source and the drain region are doped with p-type dopants. As is to be clearly understood, within the context of the present specification, the doping types may be reversed. If a specific current path is described using directional language, this description is to be merely understood to indicate the path and not the polarity of the current flow, i.e. whether the current flows from source to drain or vice versa. The Figures may include polarity-sensitive components, e.g. diodes. As is to be clearly understood, the specific arrangement of these polarity-sensitive components is given as an example and may be inverted in order to achieve the described functionality, depending whether the first conductivity type means n-type or p-type.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

1. A semiconductor device, comprising:
a semiconductor body comprising a main surface, a rear surface, and an outer edge side extending between the main surface and the rear surface;
a superjunction structure comprising a plurality of superjunction columns that alternate in conductivity type along a lateral direction of the semiconductor body;
an active region comprising a plurality of transistor cells, each of the transistor cells being configured to control a vertical current flowing through one of the superjunction columns; and
a peripheral region laterally separating the active region from the outer edge side, the peripheral region being devoid of the transistor cells,
wherein the superjunction structure comprises a first cell region and a second cell region,
wherein the first cell region is disposed within a central part of the active region, and
wherein the second cell region at least partially overlaps with an outer part of the active region that adjoins the peripheral region, and
wherein the superjunction columns in the second cell region have a lower dopant concentration than the superjunction columns in the first cell region.

2. The semiconductor device of claim 1, wherein the superjunction structure comprises a plurality of superjunction unit cells formed by adjacent pairs of the superjunction columns, and wherein the second cell region comprises at least one of the superjunction unit cells overlapping with the active region.

3. The semiconductor device of claim 2, wherein the second cell region comprises no more than three of the superjunction unit cells overlapping with the active region.

4. The semiconductor device of claim 2, wherein in the first cell region a dopant concentration of the each of the superjunction unit cells is substantially identical.

5. The semiconductor device of claim 1, wherein in the second cell region a dopant concentration of each of the superjunction columns decreases relative to an immediately laterally adjacent superjunction column moving in the lateral direction towards the outer edge side.

6. The semiconductor device of claim 1, wherein the second cell region is comprised of a plurality of the superjunction unit cells, and wherein in the second cell region a dopant concentration of each superjunction unit cell decreases relative to an immediately laterally adjacent superjunction unit cell moving in the lateral direction towards the outer edge side.

7. The semiconductor device of claim 1, wherein the second cell region overlaps with the peripheral region.

8. The semiconductor device of claim 7, wherein in the second cell region a dopant concentration of each of the superjunction columns decreases relative to an immediately laterally adjacent superjunction column moving in the lateral direction towards the outer edge side.

9. The semiconductor device of claim 1, wherein from a plan-view perspective of the semiconductor body, a dopant concentration of the of the superjunction columns is defined by same dopant-level regions, and wherein the same dopant-level regions form an enclosed ring that completely surrounds the active region.

10. The semiconductor device of claim 9, wherein from the plan-view perspective of the semiconductor body each of the same dopant-level regions within the active region form perpendicular corners with one another.

11. The semiconductor device of claim 1, wherein at an outer boundary of the active region, an outermost second conductivity type column is actively conductive in both directions.

12. The semiconductor device of claim 1, wherein in the peripheral region, the superjunction columns are arranged to maintain a same shape of an electric field as an electric field in the active region.

13. The semiconductor device of claim 1, wherein the peripheral region comprises an intrinsically or very lightly doped outer region disposed between the superjunction structure and the outer edge side of the semiconductor body.

14. A semiconductor device, comprising:
a semiconductor body comprising a main surface, a rear surface, and an outer edge side extending between the main surface and the rear surface;
a superjunction structure comprising a plurality of superjunction columns that alternate in conductivity type along a lateral direction of the semiconductor body;
an active region comprising a plurality of transistor cells, each of the transistor cells being configured to control a vertical current flowing through one of the superjunction columns;
a peripheral region laterally separating the active region from the outer edge side, the peripheral region being devoid of the transistor cells; and
a groove formed in the main surface of the semiconductor body in the peripheral region, the groove being filled with a dielectric material,
wherein a width an interior portion of the peripheral region is less than or equal to two times a cell pitch of the superjunction structure, the cell pitch being a separation distance between immediately adjacent superjunction columns of a same doping type in the superjunction structure, the width of the interior portion of the peripheral region being a lateral distance from a center of a gate trench from an outermost transistor cell from the active region a lower corner of the groove.

15. The semiconductor device of claim 14, wherein the width of the interior portion of the peripheral region is between one and two times the cell pitch of the superjunction structure.

16. The semiconductor device of claim 14, wherein the interior portion of the peripheral region comprises a body contact region that extends from the main surface between the outermost one of the superjunction columns from the active region and the lower corner of the groove, wherein the body contact region is a highly doped region of a second conductivity type.

17. The semiconductor device of claim 16, wherein the semiconductor device comprises a plurality of interior body contacts within the active region and a first outer body contact disposed adjacent the outermost one of the superjunction columns, wherein the first outer body contact forms a low-ohmic connection with the body contact region, and wherein a width of the first outer body contact is that same as a width of each of the interior body contacts.

18. The semiconductor device of claim 17, wherein a transistor cell from the outermost one of the superjunction columns comprises only one source region disposed on an inner side of the transistor cell opposite from the peripheral region.

19. The semiconductor device of claim 17, wherein the superjunction structure comprises a first cell region and a second cell region, wherein the superjunction columns in the second cell region have a lower dopant concentration than the superjunction columns in the first cell region, wherein the first cell region is disposed within a central part of the active region, wherein the second cell region at least partially overlaps with an outer part of the active region that adjoins the peripheral region.

20. The semiconductor device of claim 19, wherein in the second cell region a dopant concentration of each of the superjunction columns decreases relative to an immediately laterally adjacent superjunction column moving in a lateral direction towards the outer edge side.

21. The semiconductor device of claim 20, wherein the second cell region overlaps with the interior portion of the peripheral region.

22. The semiconductor device of claim 14, wherein from a plan-view perspective the groove comprises a radius, and wherein the radius is less than or equal to two times the cell pitch of the superjunction structure.
